(19) United States
(12) Patent Application Publication
(10) Pub. No.: US 2015/0229266 A1
(43) Pub. Date: Aug. 13, 2015

(54) CPV SYSTEM AND METHOD THEREFOR

(71) Applicant: SOUTHWEST SOLAR TECHNOLOGY LLC, Tempe, AZ (US)

(72) Inventors: HERBERT T. HAYDEN, Phoenix, AZ (US); PAUL LINDEN THOMAS, Lunenburg, MA (US)

(73) Assignee: SOUTHWEST SOLAR TECHNOLOGY LLC, Tempe, AZ (US)

(21) Appl. No.: 14/691,673

(22) Filed: Apr. 21, 2015

Related U.S. Application Data
(62) Division of application No. 13/206,258, filed on Aug. 9, 2011.

(51) Int. Cl. H02S 40/22; H02S 40/32; H01L 31/054

(52) U.S. Cl. CPC H02S 40/22; H01L 31/0547; H01L 31/0543; H02S 40/32

(57) ABSTRACT

A concentrated photovoltaic system (10) uses a semi-dense array of photovoltaic cells (76) in combination with a point-focus, reflecting primary concentrator (12) and a number of linear, refracting secondary concentrators (22). The secondary concentrators (22) are configured as totally internally reflecting lenses, wherein each lens covers an entire planar receiver tile (38) holding a multiplicity of photovoltaic cells (76). A large number of receiver tiles (38) may be used in the converter (10). The cells (76) are arranged in dense, nearly abutting, sub-arrays (92) that are spaced apart from other sub-arrays (92). Photovoltaic cells (76) from a few nearby sub-arrays are coupled in parallel to drive a DC/DC MPPT boost converter (100). DC outputs from several boost converters (100) are series coupled to form a high DC voltage string which drives a DC/AC inverter (122). AC outputs from several DC/AC inverters (122) are combined in a multi-winding transformer (124) to generate a sine wave with low harmonic distortion.

### TECHNICAL FIELD OF THE INVENTION

The present invention relates generally to concentrated photovoltaic (CPV) systems, which convert light, sunlight, and/or heat into electrical power. Specifically, the present invention relates to a CPV system and method which concentrate solar flux onto a semi-dense array of solar cells to achieve power and cost efficiencies.

### BACKGROUND OF THE INVENTION

One way in which solar to electrical power converters may be distinguished from one another is by considering whether or not they concentrate the sun's energy before the application of that energy to solar cells. At lower levels of electrical power production, cost efficient, non-concentrating systems are simpler and more common but not as energy efficient as they might be. Cost efficiency refers to the amount of money spent to produce a given amount of electrical energy. Spending less money to produce a given amount of electrical energy means that the system is more cost efficient. Energy efficiency refers to the amount of area over which solar energy is collected to produce a given amount of electrical energy. Using a smaller solar collection area to produce a given amount of electrical energy means that the system is more energy efficient. Non-concentrating systems tend to use less energy efficient photovoltaic cells because the higher cost of many highly energy efficient photovoltaic cells tends to harm cost efficiency.

But a desire exists to make solar energy converters more energy efficient at a reasonable cost. And, energy conversion systems that are more energy efficient tend to be concentrating systems, which are also called concentrated photovoltaic (CPV) systems.

One way in which CPV systems may be distinguished from one another is by considering the amount of concentration achieved. CPV systems that achieve no more than medium or lower levels of concentration (e.g., below 300 suns) are easier to successfully build and operate than systems that achieve higher levels of concentration. The “suns” unit of solar flux refers to the ratio of concentrated flux relative to unconcentrated sunlight, that is any geometric concentration achieved by optical devices, such as concentrating lenses and/or concentrating reflectors, less any optical loss. Many inexpensive, effective, and practical optical systems, including a wide variety of lenses and reflectors, are available when one needs to achieve only medium or lower levels of concentration. Aiming the collector at the sun and tracking the sun are less critical with medium or lower levels of concentration, and heat management is easily addressed. These design factors can lead to cost efficiencies for many applications at medium or lower levels of concentration when compared to CPV systems that achieve higher levels of concentration. But again, energy efficiency suffers because photovoltaic cells that achieve high levels of energy efficiency tend to do so at higher levels of concentration.

Another way in which CPV systems may be distinguished from one another is by considering the relationship between concentrating optics and solar cells. Distributed point-focus CPV systems have a one-to-one relationship between concentrating optics and solar cells. In other words, a single solar cell is driven by a single optical system dedicated to that single solar cell. That optical system may include several different lenses and/or mirrors. Typically, a large number of solar cells and corresponding large number of optical systems are mounted together and controlled by a common tracking system. But the solar cells themselves are distributed over a large area and not located near one another. In contrast, dense-array CPV systems have a one-to-many relationship between concentrating optics and solar cells. A common optical system feeds solar flux to a multiplicity of solar cells, and the solar cells are located together in one area where the common optical system concentrates its solar energy.

Distributed point-focus CPV systems have become popular in recent years and provide several desirable features. For example, heat management is addressed by distributing solar cells over a large area and using passive cooling. Passive cooling is more simple to implement than active cooling, and no electrical energy is consumed in operating cooling fans or pumps. Moreover, distributing solar cells over a large area provides a generous amount of otherwise unused space within which to make connections between the solar cells, route wiring, and to mount other components.

But distributed point-focus CPV systems suffer drawbacks as well. They are often difficult to manufacture, maintain, and upgrade. The numerous optical systems involved require numerous, separate, exacting, optical alignment steps during manufacturing, and the distributed nature of the system makes maintenance and upgrades more difficult. While the placement of wiring is typically not difficult, a large amount of connections and wiring is often required, increasing material costs and weight and making manufacturing more expensive. This wiring network extends over a large distributed area, and throughout this large area open spaces between optics, cells, wiring, and the like are desirably protected to be kept free of obstructions, shorts, and the like. And, distributed point-focus CPV systems do not adapt well to some optical systems, such as large concentrating parabolic reflectors, that can achieve very high levels of concentration (e.g., above 800 suns) over a large area at relatively low cost. Moreover, while passive cooling is often desirable, when complementary applications, such as domestic heating, water heating, desalinization, and the like, are available to make use of the waste heat from a solar to electrical power converter, no ready opportunity is available with which to collect heat for use elsewhere because the heat sources are scattered over a large area.

In order to achieve satisfactory performance, distributed point-focus CPV systems tend to wire lower-voltage individual solar cells in series to form a higher-voltage string of solar cells, then possibly combine multiple strings in other series and parallel combinations which are then fed to a DC/AC power inverter, from which AC electrical power is presented to an electrical load. Often, the power inverter is a complicated and expensive component that employs maximum power point tracking (MPPT) to present an adaptive load to the entire collection of solar cells that causes the solar cells to collectively operate at their maximum power points (i.e., most energy-efficient operating conditions). Building up higher voltage strings from individual solar cells is desirable because it allows less I²·R ohmic losses over the extensive interconnection wiring network used over a distributed area. And, it also allows electronic power-handling components to operate nearer high voltage operating limits but at less current for a given amount of power, thereby utilizing the components more efficiently and reducing component costs.

But combining lower-voltage solar cells in series to form a higher-voltage string also has its drawbacks. When a string of solar cells is combined in series, the string becomes sensitive and vulnerable to the limitations of the lowest current generated in the worst-performing solar cell in the string. Thus, great care is taken to insure that no solar cell in the string is illuminated by less solar flux than the other solar cells in the string. This may be accomplished by careful and exacting alignment among the various optic systems that drive the solar cells in the string, but the manufacturing difficulty and costs increase tremendously. And strings of series-connected solar cells require the use of bypass diodes in order to avoid damage from reverse voltages imposed by other cells in the string, but bypass diodes further increase costs and pose additional placement and interconnection design challenges.

Dense-array CPV systems have been less popular than distributed point-focus CPV systems in recent years due, at least in part, to a variety of drawbacks. For example, heat management poses a serious design challenge when the solar cells are concentrated together in a small space. Active cooling is often necessitated, and compared to passive cooling, active cooling increases costs associated with pumps, radiators, plumbing, and the like, and active cooling consumes power. The heat management problem is such a serious design challenge that concentration may be limited to being less than the optical systems' maximum power per solar flux capabilities due to a limited ability to transfer heat away from the densely arrayed solar cells.

In dense-array CPV systems, solar cells are located immediately adjacent to one another so that very little concentrated solar flux is lost due to dead spots or gaps and as much solar flux as possible irradiates the solar cells. But this placement leaves no otherwise unused space for routing conductors to the solar cells or for bypass diodes. Prior art dense-array CPV systems have been forced to accept power-efficiency reductions due to concentrated solar flux being lost in spaces made available to accommodate wiring, and/or to accept cost-efficiency reductions due to requiring solar cell configurations, such as non-planar form factors and contacts placed in difficult-to-manufacture package locations, that do not conform to industry standard semiconductor and solar cell practices.

On the other hand, dense-array CPV systems also have some attractive features. They take advantage of optical devices, such as large concentrating parabolic reflectors, that can achieve very large amounts of concentration over a large area at relatively low cost. They avoid the manufacturing, maintaining, upgrading, and excessive wiring pitfalls of distributed point-focus CPV systems by having only a single large optic to properly align rather than numerous smaller ones and by having solar cells and related wiring in one confined place rather than distributed over a large area. And, in some applications the heat from a solar to electrical energy converter may be advantageously used in another complementary application, such as desalination, thereby making the extraction of otherwise unwanted heat valuable.

Like distributed point-focus CPV systems, dense-array CPV systems interconnect individual solar cells in series to form higher-voltage strings in order to maintain ohmic losses at manageable levels and to use electrical power components efficiently. But the series-connected strings have led to the use of expensive, specialized contoured mirror optics, light tubes, and/or light distributors that homogenize the concentrated solar flux prior to irradiating the solar cells so that all solar cells receive about the same amount of solar flux (e.g., within 5 percent of each other). The use of such homogenizing optical devices is undesirable because they impose added costs and optical losses, leading to reduced energy efficiency and reduced cost efficiency. And, the series-connected strings require the use of bypass diodes, causing other design challenges concerning the placement and interconnection of bypass diodes in a limited space environment.

Accordingly, a need exists for an improved CPV system and method which address the numerous disadvantages of distributed point-focus and dense-array CPV systems and yet achieve improved energy efficiency and cost efficiency.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, and:

FIG. 1 shows a schematic view of a concentrating solar dish and a receiver used in a concentrated photovoltaic (CPV) system configured in accordance with one embodiment of the present invention;

FIG. 2 shows a schematic overview of the receiver portion of the CPV of FIG. 1 populated with a few receiver tiles;

FIG. 3 shows a perspective view of a lens used by a single receiver tile in accordance with one embodiment of the present invention;

FIG. 4 shows a schematic side view of a single receiver tile and of a portion of an adjacent receiver tile in accordance with one embodiment of the present invention;

FIG. 5 shows a schematic end view of a single receiver tile configured in accordance with one embodiment of the present invention;

FIG. 6 shows a schematic top view of a single receiver tile, but without a lens, configured in accordance with one embodiment of the present invention;

FIG. 7 shows a schematic block diagram of electrical circuits associated with a single receiver tile configured in accordance with one embodiment of the present invention; and

FIG. 8 shows a schematic block diagram of the CPV of FIG. 1 in accordance with one embodiment of the present invention.

### DETAILED DESCRIPTION OF THE PREFERRED EMBODIMENTS

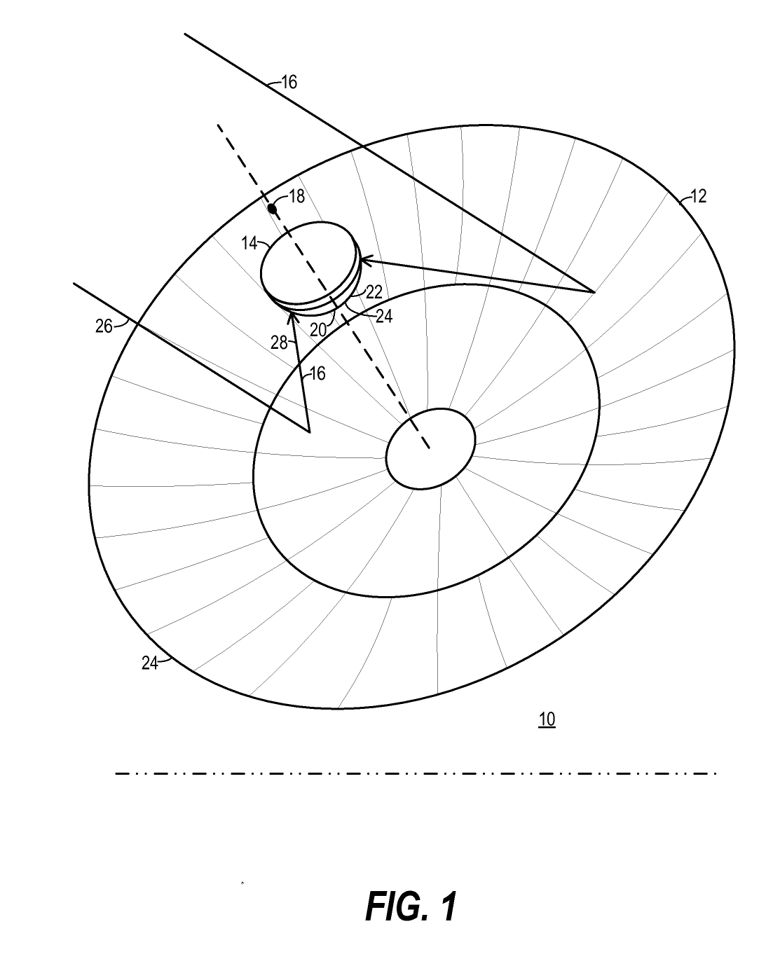

FIG. 1 shows a schematic view of a concentrated photovoltaic (CPV) system 10 configured in accordance with one embodiment of the present invention. CPV system 10 is configured to convert solar energy into electrical energy. FIG. 1 shows that CPV system 10 includes a primary concentrator 12 in the form of a concentrating parabolic reflecting dish and a receiver 14.

Primary concentrator 12 may be configured in accordance with practices known to those skilled in the art. The precise configuration, manner of manufacture, and materials used may vary considerably. The reflecting surface of primary concentrator 12 may be configured as a continuous surface or as a mosaic of flat or curved surfaces. Desirably, a vertical post or other support structure (not shown) and solar-tracking positioning system (not shown) are included, as understood by those skilled in the art, to cause primary concentrator 12 to accurately face the sun when CPV system 10 is operating and to accurately track the sun as it moves through the sky throughout the course of the day. The 360° circular dish schematically depicted in FIG. 1 may alternatively have a sector removed (not shown) to accommodate positioning of the support structure and may have a non-circular shape, including oval, elliptical, trough, or a modified form of any of these shapes.

Likewise, the area over which solar flux 16 is collected by primary concentrator 12 may vary considerably in size. In one embodiment, a dish having a collection area in the range of 240-400 m² is used to form a 100 kW CPV system 10, and in another embodiment a dish having a collection area in the range of 30-50 m² is used to form a 10 kW CPV system 10. Regardless of size, primary concentrator 12 is configured to reflect and concentrate incoming solar flux 16 toward a focusing region 18. But receiver 14 is located before focusing region 18 and absorbs as much of the solar flux 16 which irradiates primary concentrator 12 as is practical. Receiver 14 may be supported in its desired position before focusing region 18 where it absorbs as much solar flux 16 as practical in a conventional manner, such as by struts (not shown) mounted to the outer periphery of primary concentrator 12 or by a boom (not shown) extending from a removed sector (not shown) of primary concentrator 12. Receiver 14 is rigidly attached to primary concentrator 12 so that receiver 14 tracks the sun to maintain its desired position before focusing region 18 of primary concentrator 12, as primary concentrator 12 tracks the sun.

Receiver 14 has a convex surface 20 that is covered with many secondary concentrators 22. Convex surface 20 and secondary concentrators 22 face primary concentrator 12 so that solar flux 16, after reflection and concentration by primary concentrator 12, irradiates secondary concentrators 22. The profile exhibited by convex surface 20 conforms to the profile of primary concentrator 12 as much as practical so that solar flux 16 irradiates secondary concentrators 22 from a normal or nearly normal angle. Thus, convex surface 20 exhibits an approximately three-dimensional hemispheric shape in one embodiment, but may exhibit other shapes.

Primary and secondary concentrators 12 and 22 together form an optical system 24 which directs solar flux to photovoltaic cells (discussed below). Optical system 24 is highly efficient. A solar flux transmission medium 26 extending from an entry aperture for CPV system 10 to primary concentrator 12 is formed exclusively of air. In the figures, a transmission medium, such as solar flux transmission medium 26, is also represented by the ray or the solar flux, that propagates through the transmission medium. At primary concentrator 12, solar flux 16 encounters a single reflecting surface. From primary concentrator 12 to secondary concentrators 22, a solar flux transmission medium 28 is also formed exclusively of air. At each secondary concentrator 22, solar flux 16 encounters a single refracting surface in the preferred embodiment. Furthermore, in the preferred embodiment, a solar flux transmission medium extending from this refracting surface to the photovoltaic cells exhibits a substantially constant refractive index.

Optical system 24 does not include non-concentrating optical elements, such as light tubes or light distributors, which might homogenize solar flux distribution but are sources of losses. No high degree of uniformity is required of optical system 24. And, optical system 24 achieves a high degree of concentration primarily by using only two concentrating surfaces. In the preferred embodiments, optical system 24 concentrates solar flux 16 by a factor in excess of 800 suns, and preferably by a factor of 1200 or more suns. In this preferred embodiment, solar flux concentration in the range of 300-500 suns is achieved by primary concentrator 12 and additional concentration by a factor in the range of 3-5 is achieved through secondary concentrators 22. Those skilled in the art will appreciate that an ability to operate at high degrees of concentration causes photovoltaic cells to improve the energy efficiency and cost efficiency at which they convert solar flux into electrical power.

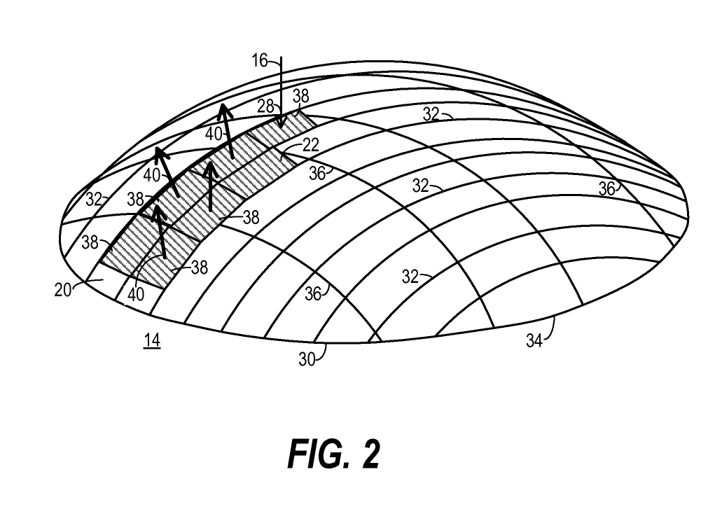

FIG. 2 shows a schematic overview of receiver 14. More specifically, FIG. 2 shows convex surface 20 of receiver 14. In comparison to FIG. 1, FIG. 2 shows convex surface 20 pointing up for illustrative purposes rather than down, but convex surface 20 and secondary concentrators 22 are nevertheless configured to face primary concentrator 12. Convex surface 20 is defined by a frame 30 of rigid arcuate shaped ribs 32 connected at the ends of ribs 32 to a rigid circular tube 34. Rigid, arcuate shaped cross members 36 may intersect ribs 32 for mechanical support. In one embodiment ribs 32, members, and/or circular tube 34 are configured as hollow tubes or pipes and configured to convey and distribute cooling fluid over convex surface 20.

FIG. 2 also shows a few receiver tiles 38 mounted to frame 30. Receiver tiles 38, including all constituent components of each receiver tile 38, are mounted to frame 30 so that substantially the entirety of frame 30 is covered by receiver tiles 38. But FIG. 2 shows only a few receiver tiles 38 mounted on frame 30 so that their relationship with frame 30 is apparent. More specifically, receiver tiles 38 are mounted to cover as much of convex surface 20 as receives concentrated solar flux 16 from primary concentrator 12 (FIG. 1), including peripheral areas which are irradiated only at the outer limits of expected alignment errors. Desirably, each receiver tile 38 is configured to be as nearly identical to the others as practical to maximize cost efficiencies. A multiplicity of receiver tiles 38 may be mounted to frame 30.

Even though surface 20 is a curved convex surface, each receiver tile 38 is roughly planar, further improving cost efficiencies by minimizing the use of curved shapes, particularly for components that are replicated a multiplicity of times in CPV system 10. In one preferred embodiment, an outward facing surface of each receiver tile 38 is covered by a single secondary concentrator 22. An outer periphery of this single secondary concentrator 22 defines the outer periphery of its receiver tile 38. Since planar receiver tiles 38 are mounted to curved frame 30, each receiver tile 38 and its secondary concentrator 22 face in a unique direction 40 perpendicular to the plane of the receiver tile 38. Each facing direction 40 is nonparallel with the other directions 40. Desirably, each direction 40 is opposite to the direction the vast majority of incident solar flux 16 travels from primary concentrator 12 (FIG. 1) to receiver 14, given the position of the receiver tile 38 on frame 30 and the positioning of receiver 14 relative to primary concentrator 12.

FIG. 2 also shows that receiver tiles 38 are mounted on frame 30 to be adjacent to one another without significant gaps there between. Gaps between receiver tiles 38 would be undesirable because concentrated solar flux 16 falling on any gap would be lost and therefore unconvertible into electrical energy. But, practical manufacturing tolerances and thermal expansion considerations may dictate that some minimal gap nevertheless exists. Desirably, any such tile gap is held to an insignificant level.

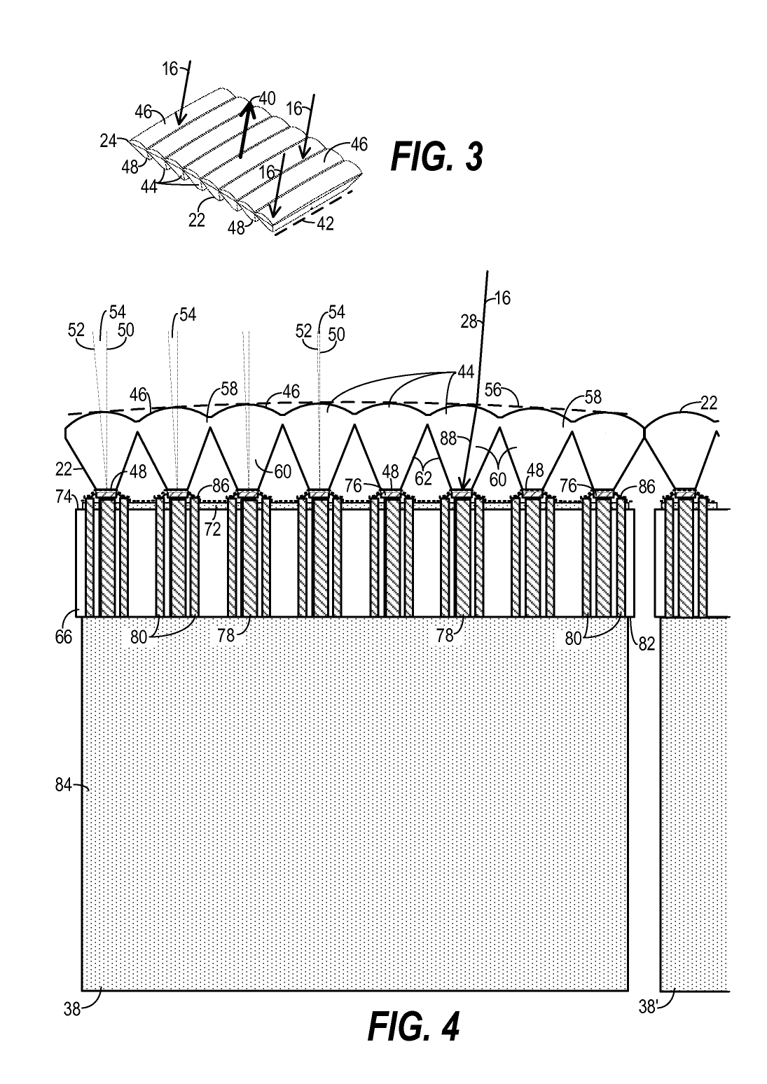

FIG. 3 shows a perspective view of a secondary concentrator 22 in the form of a lens as used on a single receiver tile 38 (FIG. 2) in one embodiment of the present invention. Desirably, each receiver tile 38 is configured as nearly identical to the others as practical, so secondary concentrator 22 is desirably replicated a multiplicity of times in receiver 14 and CPV system 10 (FIG. 1). Secondary concentrator 22 is the portion of optical system 24 that also serves as a portion of a receiver tile 38.

Secondary concentrator 22 is a linear concentrator. It focuses its incident solar flux 16 along a line 42 rather than at a point. Line 42 desirably has a width commensurate with the width of the entry aperture of a photovoltaic cell. Moreover, secondary concentrator 22 is a multi-faceted linear concentrator because it is configured to direct incident solar flux into a plurality of discrete sections 44, where each of discrete sections 44 has its own focus line 42. FIG. 3 depicts only one of focus lines 42 for the sake of clarity. In one preferred embodiment, secondary concentrator 22 is configured to have eight of discrete sections 44. Desirably, secondary concentrator 22 is formed from an optically and environmentally suitable glass as an integral unit by a molding or extrusion process to improve cost efficiencies.

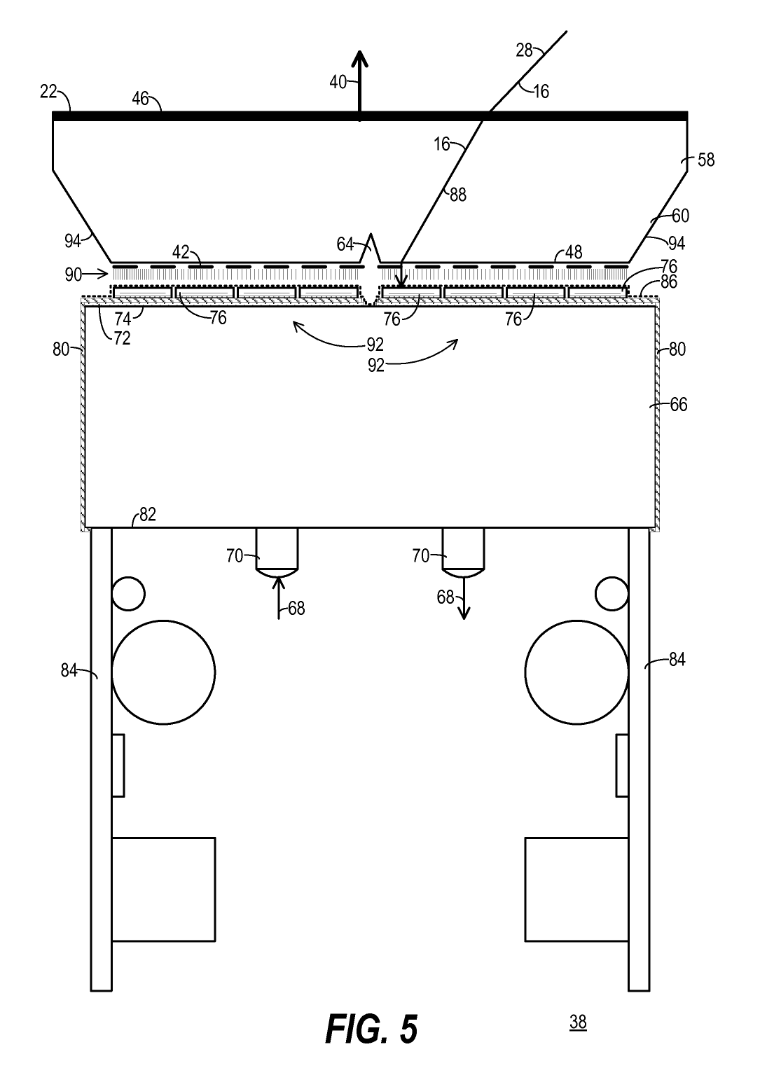

FIGS. 4 and 5 respectively show side and front schematic side views of a single receiver tile 38, including its constituent components. In FIGS. 4-5, the various components of receiver tile 38 are not shown to scale, and in FIG. 5 secondary concentrator 22, also referred to below as lens 22, is shown separated from and lifted above its normal position, which is more accurately detailed in FIG. 4. FIG. 4 also shows a portion of an adjacent receiver tile 38′ located adjacent to a complete receiver tile 38 without a significant gap there between.

Referring to FIGS. 4-5, solar flux 16 irradiates receiver tile 38 at lens 22. As depicted in FIG. 4, when an adjacent receiver tile 38′ is located so that no significant gap exists between it and receiver tile 38, it is respective lenses 22 that establish the absence of a significant gap there between. Significant gaps very well may exist between other components of adjacent receiver tiles 38.

Solar flux 16 encounters a boundary between the solar flux transmission medium 28 of air and the material of which lens 22 is formed (e.g., glass) at an entry surface 46. Entry surface 46 has a multi-convex shape in two dimensions, best viewed in FIGS. 3-4, which is configured to direct solar flux 16 into multiple discrete sections 44 of lens 22.

From the perspective depicted in FIG. 4, solar flux 16 exits lens 22 at multiple exit surfaces 48. Exit surfaces 48 are spaced apart from one another by an air gap, are substantially planar in and of themselves, and are coplanar with each other. One exit surface is provided for each discrete section 44.

For reference purposes, FIG. 4 depicts dotted lines 50 perpendicular to exit surfaces 48 extending through entry surface 46. Lines 50 lie along direction 40 for receiver tile 38, discussed above in connection with FIG. 2. FIG. 4 also shows various planes of symmetry 52 relative to perpendicular lines 50. Planes of symmetry 52 appear as mere dotted lines in FIG. 4, but if shown in FIG. 5 would extend in both of the two dimensions represented in FIG. 5. For each discrete section 44 of lens 22, entry surface 46 exhibits a convex curve which is symmetrical about its own plane of symmetry 52. But planes of symmetry 52 are offset from perpendicular lines 50 by an angle 54 that differs for each of multiple discrete sections 44, with larger angles appearing toward the outside of lens 22 and smaller angles appearing in the more centrally located discrete sections 44. In the embodiment depicted in FIG. 4, angle 54 falls in the range of −5° to +5°, but angle 54 may vary over larger or smaller ranges in different embodiments.

Furthermore, FIG. 4 depicts a dotted larger convex curve 56 extending over most of entry surface 46 and tangential to entry surface 46 at each of planes of symmetry 52. Roughly speaking, larger convex curve 56 indicates that for discrete sections 44 located toward the outside of lens 22 entry surface 46 is located nearer to exit surface 48 than for more centrally located discrete sections 44.

The configuration of entry surface 46 as defined by angles 54 and/or larger convex curve 56 compensates for the planarity of receiver tile 38. As discussed above, convex surface 20 (FIGS. 1-2) conforms to the shape of primary concentrator 12 so that the vast majority of solar flux 16 is incident upon receiver 14 at a nearly perpendicular angle throughout convex surface 20. But over the comparatively small surface of a single, roughly planar, receiver tile 38, the angle of incidence varies slightly due to the planarity of the receiver tile 38. Thus, entry surface 46 is contoured to compensate for this variance in angle of incidence so that the vast majority of solar flux 16 has a more nearly normal angle of incidence at planes of symmetry. Optical efficiency improves as a result.

Adjacent to, and immediately beneath entry surface 46 in lens 22 from the perspective of FIGS. 4-5, flux 16 encounters a continuous refractive index region 58 of lens 22. In continuous refractive index region 58 no boundary with any different material exists, except around the periphery of lens 22 where a lens-air boundary exists. In continuous refractive index region 58 there is no distinction between the multiple discrete sections 44. Continuous refractive index region 58 serves to attach multiple discrete sections 44 together so that they may be manufactured as a unit and installed in receiver tile 38 as a unit, thereby improving cost efficiencies. Moreover, this attachment between discrete sections 44 lessens any gap loss that might otherwise occur between multiple discrete sections 44 and provides protection from the elements, such as rain, dust, and debris, for other components that reside in receiver tile 38. Desirably, continuous refractive index region 58 extends for only a small thickness within lens 22 to minimize optical losses associated with lens 22 and to minimize the weight of lens 22. But this small thickness is desirably sufficient to insure the mechanical stability of lens 22.

After continuous refractive index region 58, flux 16 encounters a totally internally reflecting (TIR) side profile region 60, best viewed in FIG. 4. Multiple discrete sections 44 are physically identifiable within region 60 because discrete sections 44 are spaced apart from each other by air gaps. For each discrete section 44, walls 62 of lens 22 taper toward the section's plane of symmetry 52. Walls 62 form a lens-air boundary, which exhibits a significant abrupt reduction in index of refraction. The angle of taper is sufficiently small so that total internal reflection results at walls 62 within TIR side profile region 60. In the embodiment depicted in FIG. 4 this angle of taper results in adjacent walls 62 for adjacent discrete sections 44 being positioned at an angle of less than 45°. While FIG. 4 depicts walls 62 as being substantially flat, in other embodiments walls 62 may exhibit a more contoured shape. Within TIR side profile regions 60, solar flux 16 is further concentrated and directed toward exit surfaces 48. The use of total internal reflection in lens 22 in concentrating solar flux 16 makes lens 22 a totally internally reflecting lens, results in virtually no boundary loss of solar flux 16 in TIR side profile region 60, and results in further energy efficiency improvement. In the preferred embodiment, in at least the one horizontal dimension shown in FIG. 4, entry surface 46 spans a distance that is at least two times greater than the sum of all distances spanned by exit surfaces 48, causing lens 22 to achieve flux concentration greater than a factor of two.

TIR side profile region 60 ends at exit surfaces 48. The width of each exit surface 48, as best viewed in FIG. 4, is desirably as precisely equal to the corresponding width of an entry aperture for a single photovoltaic cell (discussed below) as practical. But the length of each exit surface 48 may extend for the entire length of lens 22, as best viewed in FIG. 5. In other words, the length of exit surface 48 may extend over a distance far greater than the corresponding length of an entry aperture for a single photovoltaic cell.

FIG. 5 depicts the length of each exit surface 48 as being divided into two sections, with an upwardly extending notch 64 separating the two sections. Notch 64 defines another lens-air boundary. Desirably, notch 64 exhibits walls at sufficiently steep angles to insure total internal reflection at these walls within lens 22, but a reflective material may be applied to these walls in an alternative embodiment. Notch 64 represents an accommodation to the use of a particular ceramic insulating material (discussed below) which cannot accommodate the entire length of lens 22 depicted in FIG. 5. Notch 64 may be omitted in other embodiments, or may be duplicated for each juncture between adjacent photovoltaic cells. Thus, lens 22 is configured to prevent solar flux 16 from exiting lens 22 in the vicinity of notch 64. For each exit surface 48, solar flux 16 propagating within lens 22 and encountering notch 64 is reflected along the length of exit surface 48 toward the ends of exit surface 48.

FIG. 5 shows that entry surface 46 of lens 22 extends in a substantially straight line for the length dimension depicted horizontally in FIG. 5. This embodiment is desirable because it is compatible with forming lens 22 using an inexpensive extrusion process. But an alternate embodiment may cause entry surface 46 to exhibit a shallow convex curve in this dimension, similar to convex curve 56 shown in FIG. 4. Such a convex curve could be used to compensate for the planarity of receiver tile 38 and better conform lens 22 to the shape of primary concentrator 12 (FIG. 1), yielding a slight further improvement in optical efficiency. While this alternate embodiment remains compatible to a molding lens-forming process, it may be less compatible with a extrusion lens-forming process.

A planar heat sink 66, in the form of a liquid-cooled heat plate for the embodiment depicted in the Figures, serves as a substrate for each receiver tile 38. As shown in FIG. 5, a cooling fluid 68, depicted as arrows in FIG. 5, may be circulated through heat sink 66 at fluid entry and exit ports 70. Heat sink 66 may be formed as a hollow container through which cooling fluid 68 circulates, having exterior and interior surfaces which readily accommodate heat transfer, and being otherwise configured to promote heat transfer to cooling fluid 68. The exterior surfaces of heat sink 66 are likely to be electrically conductive as well. Accordingly, an electrically insulating cladding 72 may be applied to a photovoltaic side 74 of heat sink 66. Photovoltaic side 74 is the side of heat sink 66 on which photovoltaic cells 76 are mounted. Desirably cladding 72 is formed of a material that is a good conductor of heat. Alumina or other ceramics may be used for such a material.

Opposing polarity, positive and negative electrically conductive busses 78 and 80 are applied over cladding 72 (FIG. 4) in a pattern that is discussed in more detail below. Busses 78 and 80 also extend from photovoltaic side 74 of heat sink 66 around the ends of heat sink 66 (FIG. 4) to a circuit board side 82 of heat sink 66. Circuit board side 82 opposes photovoltaic side 74 and represents the side of heat sink 66 on which circuit boards 84 are mounted and the side away from which circuit boards 84 project. As discussed in more detail below, circuit boards 84 provide DC/DC boost converter circuits, with two DC/DC boost converters provided per circuit board 84 in the preferred embodiment. In one embodiment, cladding 72 may also be applied at the ends of heat sink 66 so that busses 78 and 80 are bare conductors attached to cladding 72 and insulated from each other and from heat sink 66 by cladding 72. In another embodiment, suitable insulation may be applied over busses 78 and 80 in the vicinity of the ends of heat sink 66 so that cladding 70 may be omitted on the ends.

Desirably, photovoltaic cells 76 are configured in accordance with industry standards, including packaging and lead frame or contact positioning. The use of industry standard photovoltaic cells 76 improves cost efficiencies. In accordance with such standards, photovoltaic cells 76 are provided in a planar package in which a positive contact appears on the bottom (i.e., opposite the flux entry aperture) of the package, and negative contacts are provided on opposing side walls of the top of the package. A wide variety or standard manufacturing methodologies and materials may be used in the construction of photovoltaic cells 76. Desirably, photovoltaic cells 76 are based on semiconductor alloys that achieve relatively high voltages and relatively high energy efficiency when irradiated with solar flux concentrated to a flux density of more than 800 suns.

Photovoltaic cells 76 are mounted on photovoltaic side 74 of heat sink 66 over positive electrical busses 78 so that the positive contacts of photovoltaic cells 76 make reliable, high conductivity electrical connections with positive electrical busses 78. In addition, photovoltaic cells 76 are mounted so that an efficient thermal coupling is provided to heat sink 66 through bus 78 and cladding 72. With this mounting, negative busses 80 extend alongside photovoltaic cells 76 so that the negative leads of photovoltaic cells 76 make reliable, high conductivity electrical connections with negative electrical busses 80. The placement of photovoltaic cells 76 relative to one another is discussed in more detail below. Flux entry apertures for all photovoltaic cells 76 are coplanar for each receiver tile 38 and face in the same facing direction 40 (FIG. 2) for each receiver tile. But as discussed above, facing directions 40 are nonparallel for different receiver tiles 38.

After securing photovoltaic cells 76 to heat sink 66, a protective coating 86 is applied over photovoltaic cells 76. Protective coating 86 serves to protect photovoltaic cells 76 from the elements. In addition, protective coating 86 is configured to be as optically lossless as practical and to optically couple or otherwise fill the space between lens 22 and photovoltaic cells 76.

Moreover, protective coating 86 is desirably configured to exhibit a refractive index somewhere between the refractive indexes of the material from which lens 22 is formed and the material from which the flux entry aperture of photovoltaic cells 76 is formed. A solar flux transmission medium 88 which extends from entry surface 46 of lens 22 to active circuitry of photovoltaic cells 76 exhibits a substantially constant refractive index. For example, each of lens 22, coating 86, and the flux entry aperture of photovoltaic cells 76 may exhibit a refractive index within ±5 percent of 1.47. While dissimilar-material boundaries exist within solar flux transmission medium 88, refractive indexes are substantially constant on both sides of such boundaries, resulting in an efficient transmission of solar flux 16 to photovoltaic cells 76. Very little internal reflection occurs at exit surfaces 48 of lens 22.

Those skilled in the art will appreciate from the above discussion that optical system 24 (FIGS. 1-2) is configured to direct differing amounts of solar flux to different ones of photovoltaic cells 76. No optical device is included to homogenize the flux density over different photovoltaic cells 76. FIG. 5 is shown with lens 22 spaced above and apart from photovoltaic cells 76 for purposes of illustration so that an exemplary flux density distribution 90 over two linear sub-arrays 92 of photovoltaic cells 76 may be shown. In operation, exit surface 48 of lens 22 is in contact with coating 86. Within each sub-array 92, photovoltaic cells 76 are collinearly positioned, without significant gaps between adjacent ones of cells 76. As with receiver tiles 38, gaps between photovoltaic cells 76 are highly undesirable because concentrated solar flux 16 falling on any gap would be lost and therefore unconvertible into electrical energy. But, practical manufacturing tolerances and thermal expansion considerations may dictate that some minimal gap nevertheless exist. Desirably, any such cell gap is far less (e.g., <5 percent) than the width of any single cell 76 and is held to an insignificant level. While a gap exists between sub-arrays 92, notch 64 in lens 22 is provided to direct solar flux 16 away from this particular gap.

Flux density distribution 90 is depicted as a series of short vertical lines in FIG. 5. Closely spaced lines indicate more flux density, while more distantly spaced lines indicate less flux density. In the exemplary flux density distribution 90 shown in FIG. 5, greater amounts of flux are delivered to the ends of sub-arrays 92 than to the central regions of sub-arrays 92. This distribution results, at least in part, from the tapered ends 94 of lens 22 and notch 64 depicted in FIG. 5. Tapered ends 94 are also formed at an angle that results in total internal reflection within lens 22.

In prior art CPV systems that employ light distributors or light tubes to homogenize flux density or that employ separately aligned optics for each photovoltaic cell, designs and alignment procedures are configured so that each series-coupled photovoltaic cell in a string receives within 5 percent of the average flux density that is received by each other cell in the string. This results in the same flux density at each cell in the string, which prevents any one cell from producing less electrical current than the other cells in the string. But in accordance with the preferred embodiment, different amounts of solar flux (e.g., greater than 5 percent average flux density variation among cells 76) are easily tolerated without any loss of energy efficiency, as is discussed below in more detail.

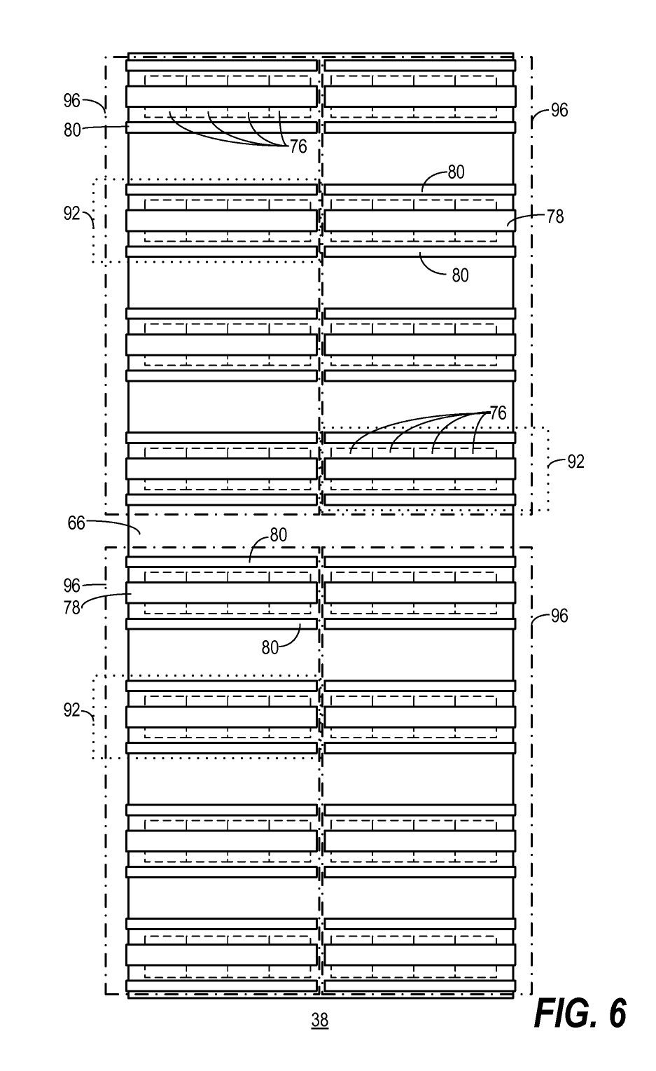

FIG. 6 shows a schematic top view of a single receiver tile 38 without a lens 22. Thus, FIG. 6 depicts the spatial relationships among photovoltaic cells 76 and the layout of positive and negative busses 78 and 80. Photovoltaic cells 76 are shown as dotted-line boxes in FIG. 6. As discussed above, all receiver tiles 38 are desirably configured as nearly identical as practical.

For the embodiment depicted in FIG. 6, each discrete section 44 of lens 22 (FIGS. 3-5) has an exit surface 46 that provides solar flux 16 to a row of photovoltaic cells 76 through coating 86 (FIGS. 4-5). As also shown in FIG. 5, each row of cells 76 includes two sub-arrays 92 of adjacent, nearly abutting, collinear photovoltaic cells 76. Each sub-array 92 has at least two photovoltaic cells 76, with four photovoltaic cells 76 being depicted in the embodiment of FIG. 6. But the rows of photovoltaic cells 76 are spaced apart from one another and parallel to one another. Accordingly, the entire collection of photovoltaic cells 76 in CPV system 10 (FIG. 1), considered over all receiver tiles 38, is quite dense when compared to conventional distributed point-focus CPV systems because of the spacing of a large number of photovoltaic cells 76 adjacent to one another without significant gaps there between and the nearby presence of other photovoltaic cells 76 that are spaced a small distance apart. But it is not as dense as a conventional dense-array CPV system because a significant amount of inactive space is provided within receiver 14 (FIG. 1) near and around photovoltaic converters 76 due to the concentration achieved by secondary concentrators 22. This inactive space is useful for making interconnections, routing conductors, and for allowing heating from photovoltaic cells 76 to be distributed over a larger area, where it can be removed more easily than occurs with conventional dense arrays. As a result, very high levels of flux concentration can be efficiently directed to photovoltaic cells 76, and the resulting heat easily removed. The arrangement of photovoltaic cells 76 within CPV system 10 may be deemed a semi-dense array.

For each sub-array 92, a positive bus 78 is sandwiched between photovoltaic cells 76 and heat sink 66. Two negative busses 80 are provided for each sub-array 92, and the two negative busses 80 extend alongside photovoltaic cells 76, parallel to the sub-array's positive bus 78. This arrangement results in electrically coupling all photovoltaic cells 76 in sub-array 92 in parallel, with no two cells coupled together in series. For the embodiment shown in FIG. 6, the two sub-arrays 92 included per row need not be coupled together as their busses remain isolated from one another. The coupling of cells 76 in parallel leads to a more orderly interconnecting scheme than series connections, where a large number of separate conductors need to be kept isolated from one another. Using industry standard photovoltaic cell packaging, photovoltaic cells 76 may be located adjacent to one another without significant gaps there between to accommodate wiring or other components. Moreover, the coupling of cells 76 in parallel allows CPV system 10 to escape the requirement for maintaining the same flux density at each cell in a group of cells that are coupled together because differing currents can add, while voltages are essentially the same at a common temperature.

Moreover, sub-arrays 92 may be grouped together to form arrays 96. In the embodiment shown in FIG. 6, each quadrant of receiver tile 38 forms an array 96 that includes four, spaced apart, parallel, sub-arrays 92. On any given receiver tile 38, each array 96 has two adjacent arrays 96, and the tile's single lens 22 concentrates and directs solar flux 16 to all photovoltaic cells 76 included in four separate arrays 96. Additional adjacent arrays 96 may be provided by adjacent receiver tiles 38, depending on the receiver tile 38 placement within receiver 14. All photovoltaic cells 76 in an array 96 are coupled in parallel, with no two coupled in series, so arrays 96 each include a number (16 depicted in the figures) of parallel-coupled photovoltaic cells 76. The respective positive busses 78 for each sub-array 92 in an array 96 are coupled together at circuit board 84 (FIGS. 4-5) or elsewhere, and the respective negative busses 80 for each sub-array 92 in an array 96 are coupled together at circuit board 84 or elsewhere. While this embodiment shows the use of 16 photovoltaic cells 76 per array 96, other embodiments may use other numbers of cells 76, preferably in the 4-50 range to optimize cost and energy efficiencies in the DC/DC boost converters located on circuit boards 84 (FIGS. 4-5). And, nothing requires this precise grouping of sub-arrays 92 into arrays 96. In other embodiments, an array 96 may be formed only from all photovoltaic cells 76 in a single collinear sub-array 92, from all photovoltaic cells 76 in one or more desirably adjacent rows, and the like.

Since all cells 76 in array 96 are coupled in parallel, they all operate at the same voltage but may generate different amounts of current. And, the currents generated by typical photovoltaic cells 76 are sensitive to flux density, with different amounts of flux irradiating different cells 76, as described above, causing the different cells 76 to produce different amounts of current. On the other hand, the voltages generated by typical photovoltaic cells 76 are not very sensitive to flux density, so the parallel coupling of photovoltaic cells has few flux density variation ramifications.

Voltages generated by typical photovoltaic cells 76 are somewhat sensitive to temperature. Accordingly, all photovoltaic cells 76 that are coupled in parallel in an array 96 are maintained at about the same temperature. This is accomplished by having all photovoltaic cells 76 in each array 96 being mounted on a common heat sink 66 (FIGS. 4-5) and even in a common quadrant of heat sink 66 in the preferred embodiment. The use of a common heat sink 66 minimizes temperature variations among cells 76 of any given array.

Moreover, the grouping of parallel-coupled photovoltaic cells 76 located in a common quadrant of a receiver tile 38 together into an array 96 allows the use of short, high-conductivity (i.e., low resistance) interconnections from photovoltaic cells 76 to DC/DC boost converters located nearby on circuit boards 84 (FIGS. 4-5). This arrangement leads to reduced ohmic losses and improved energy efficiency.

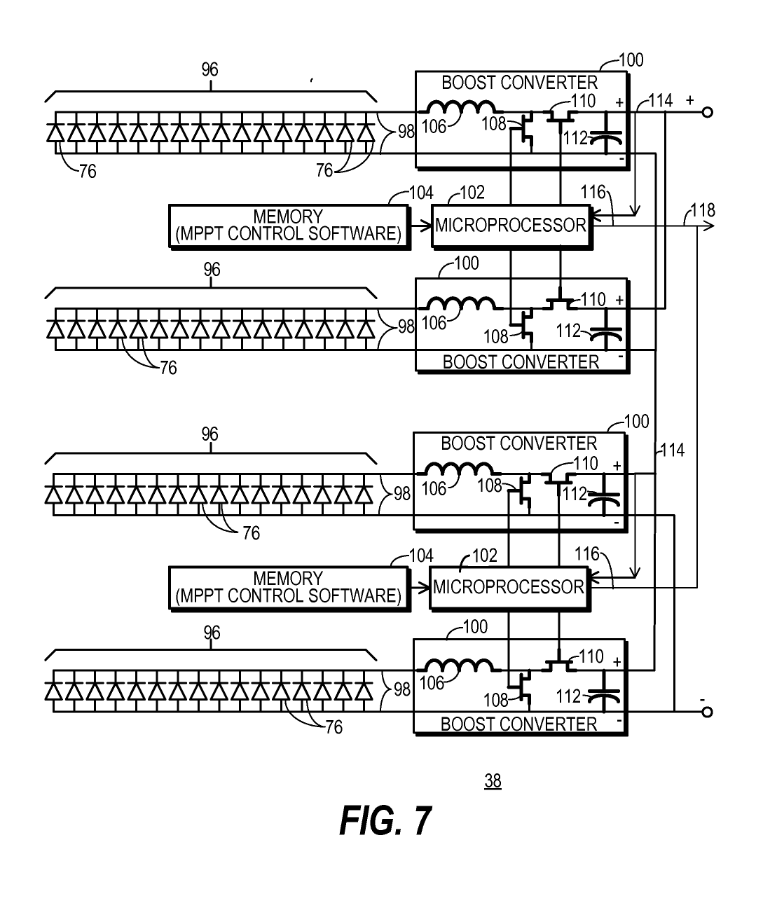

FIG. 7 shows a schematic block diagram of electrical circuits associated with a single receiver tile 38. In FIG. 7, four arrays 96 of parallel-coupled photovoltaic cells 76 are provided, with cells 76 being positioned as discussed above in connection with FIGS. 4-6. While any number of cells 76 may be coupled together in parallel for each array 96, a number in the range of 4-50 cells 76 is preferable for energy and cost efficiency purposes. FIG. 7 depicts each array 96 as having 16 cells 76. When illuminated to even a small degree and driving an appropriate electrical load, each array 96 produces a one-cell DC voltage 98, which is less than 3.25 VDC and typically around 2.6 VDC for 3-junction photovoltaic cells. This is the same one-cell voltage 98 that would be produced if a single photovoltaic cell, not electrically coupled to any other photovoltaic cell, were illuminated. And, one-cell voltage 98 changes very little as solar flux density increases or decreases. Rather, it is the electrical current that changes dramatically with flux density.

Each array 96 feeds its one-cell voltage 98 to an input of a DC/DC boost converter 100. For each array 96, boost converter 100 provides the electrical load experienced by array 96 of photovoltaic cells 76. Boost converter 100 is located on circuit board 84. Desirably, one boost converter 100 is provided for each array 96; two boost converters 100 are located on each of the two circuit boards 84 shown in FIG. 5; and, each circuit board 84 includes a common microprocessor 102 or other controller, microcontroller, state machine, or the like, and memory 104 configured to store computer software that instructs microprocessor 102 how to control the operation of the two boost converters 100 located on the circuit board 84. In other words, microprocessor 102 and its software stored in memory 104 are shared by both DC/DC boost converters 100 located on a circuit board 84. Nothing requires microprocessor 102 and memory 104 to be located in different semiconductor devices.

Each boost converter 100 is desirably configured to be as nearly identical to the other boost converters 100 as practical. Each boost converter 100 may be configured in accordance with practices known to those skilled in the art. But particular attention is paid to minimizing ohmic losses in boost converters 100 because boost converters 100 operate at unusually low voltages and unusually high currents. Ohmic losses in high current circuits are undesirable because they result in high power loss. Thus, minimizing ohmic losses improves energy efficiency. Each boost converter 100 may have an inductive component 106, switching component 108, rectifying component 110, and capacitive component 112 arranged as shown in FIG. 7 or in other ways known to those skilled in the art.

For each boost converter 100, a microprocessor 102, under the control of software stored in memory 104, serves as a maximum power port tracking (MPPT) controller for the boost converter 100. Thus, the electrical power obtained from solar flux 16 (FIGS. 1-5) directed to each array 96 by lens 22 (FIGS. 3-5) is managed by a boost converter 100. Generally, microprocessor 102 monitors a boosted voltage 114 generated at an output of boost converter 100, then controls switching element 108 to maintain that voltage, at a desired level, to the extent permitted by the power supplied at the input to boost converter 100. The parallel coupling of photovoltaic cells 76 in each boost converter's array 96 obviates the need for bypass diodes that are often used in prior art solar energy converters because no photovoltaic cell 76 can get reverse biased from the other photovoltaic cells.

For each boost converter 100, a microprocessor 102, under the control of software stored in memory 104, also causes the boost converter 100 to perform active shorting. Microprocessor 102 desirably monitors a sufficient number of parameters from boost converter 100 to determine whether current is flowing through the output terminals of boost converter 100 even though no power is being provided to input terminals of the boost converter 100. For example, microprocessor 102 may monitor current flowing at one of the output terminals, current flowing at one of the input terminals, input voltage, output voltage, and the like. Software is desirably configured to induce active shorting by switching rectifying element 110 and switching element 108 to their “on” or conducting states whenever current is flowing through output terminals without power being provided to the input terminals. This active shorting function promotes the coupling of the output of boost converter 100 in series with the outputs of other boost converters 100. Even if one boost converter 100 may be unable to produce power, due for example to an off-tracking error or the presence of debris that obstructs solar flux to an array 96 of photovoltaic cells, that boost converter 100 may still safely conduct current being generated at other series-connected boost converters 100.

In the preferred embodiment, the desired output voltage level is in the range of 2-6 times one-cell voltage 98, or 5-12 VDC. By controlling switching element 108 and operating rectifying element 110 to perform rectification, the load presented to array 96 of photovoltaic cells 76 is maintained at that level which causes photovoltaic cells 76 in array 96 to operate approximately at their maximum power points. Those skilled in the art will appreciate that the maximum power point occurs at the operating conditions where an increase in current will result in a sufficient decrease in voltage so that power diminishes, or an increase in voltage will result in a sufficient decrease in current so power diminishes. Software stored in memory 104 may be configured so that a dither algorithm is executed to continuously alter to only a slight degree the load presented to photovoltaic cells 76 thereby perturbing the current operating condition and monitoring whether the perturbation results in an increase or decrease in power production.

A communication port 116 associated with each microprocessor 102 couples to a system-level communication bus 118 to provide data communications concerning the operation of each boost converter 100.

The outputs of the each pair of boost converters 100 that share a common microprocessor 102 are desirably coupled in parallel. This parallel coupling permits the use of a common voltage reference for microprocessor 102 and its two boost converters 100, which improves cost efficiencies.

Other than parallel coupling the boost converters 100 that share a common microprocessor, desirably, outputs of boost converters 100 are coupled in series to efficiently build up the voltage presented at the output of any boost converter pair. The series-coupled outputs provide the power output for receiver tile 38. The series coupling of outputs for the four boost converters 100 located in a single receiver tile 38 allows the receiver tile 38 to produce power at an output voltage level of around 4-12 times one-cell voltage 98. Desirably, this coupling of outputs is the only cross-coupling that occurs in receiver tile 38, with control loops that manage the operation of boost converters 100 operating independently from each other.

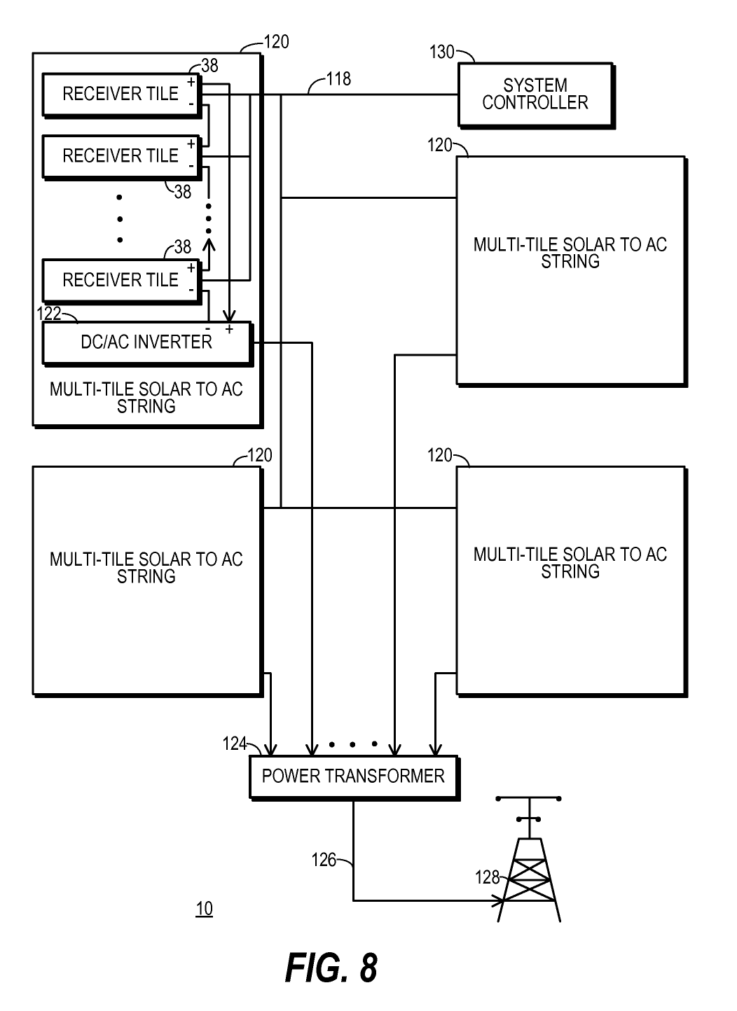

FIG. 8 shows a schematic block diagram of CPV system 10, based on the receiver tile 38 block diagram depicted in FIG. 7. CPV system 10 includes a plurality, and preferably at least four, multi-tile solar to AC string blocks 120. Each block 120 includes a number of receiver tiles 38, with the outputs of receiver tiles 38 coupled together in series. Desirably, within a single block 120, outputs from receiver tiles 38 are series coupled to achieve a voltage in the range of 50-500 VDC. This series coupled string of boost converters 100 from receiver tiles 38 is then provided to an input of a DC/AC inverter 122. DC/AC inverter 122 may, but need not, be physically located near the receiver tiles 38 included in its string.

DC/AC inverter 122 is preferably configured as a square wave, line-commutated inverter. No MPPT function need be included in inverter 122 because the MPPT function is replicated in each boost converter 100 (FIG. 7) in each receiver tile 38. Switching speeds are considered to be low speed due to the line commutation. Since such inverters use a minimal number of components and may omit the use of magnetic devices, they are inexpensive, thereby promoting the overall cost efficiency of CPV system 10. Moreover, they are highly energy efficient. But their square output waveforms contain unwanted harmonics.

Each block 120 is desirably configured the same as the others, except that the DC/AC inverters 122 in blocks 120 are commutated at different timing instants to produce different phase waveforms. This phase selection allows the use of passive harmonic cancellation in a multi-winding power transformer 124. Accordingly, AC outputs from DC/AC inverters 122 and blocks 120 are combined in transformer 124 in the proper phase relationships to perform passive harmonic cancellation in synthesizing sine waves output from transformer 124. Desirably, the commutation of inverters 122 and coupling in transformer 124 are configured to efficiently produce a 3-phase AC power line 126 with total harmonic distortion at less than 5 percent, further contributing to improved energy efficiency for CPV system 10.

Power line 126 couples to an electrical load 128, which in one embodiment is a public power distribution grid operating at a fixed voltage. Numerous MPPT boost converters 100 (FIG. 7) operate independently of each other to cause all photovoltaic cells 76 (FIGS. 4-7) to seek operation approximately at their MPP points while each multi-tile solar to AC string 120 causes the string's boost converters 100 (FIG. 7) to operate at the same current due to the series-connected outputs. And, the total voltage provided by boost converters 100 in the string 120 corresponds to the system voltage, as determined by load 128. This string current could be at a level anywhere in a range from zero to a maximum current. If a solar flux imbalance causes any boost converter's output voltage to decrease at the string's current, then other boost converters 100 will increase their output voltages to compensate, provided that most continue to operate at a roughly similar level of power. Thus, power control is distributed throughout CPV system 10 due to the independent operation of numerous boost converters 100.

A system controller 130 may be provided by a general purpose computer and is configured to couple to and control system level communication bus 118. Through communications bus 118 detailed data gathering operations concerning the low level operations of CPV system 10 are performed for analysis, repair, maintenance, and reconfiguration purposes.

In summary, at least one embodiment of the present invention provides an improved CPV system. In accordance with at least one embodiment, a CPV system with a semi-dense array of photovoltaic cells is provided. In accordance with at least one embodiment, high energy efficiency and high cost efficiency are achieved in a CPV system. In accordance with at least one embodiment, photovoltaic cells included in numerous arrays are coupled in parallel to accommodate large variances in flux density. In accordance with at least one embodiment, an optical system is provided that efficiently provides highly concentrated solar flux to the semi-dense array of photovoltaic cells. In accordance with at least one embodiment, a mosaic of roughly planar receiver tiles is configured to fit together and cooperate with one another in an manner which efficiently couples optical and electrical systems together.

Although the preferred embodiments of the invention have been illustrated and described in detail, it will be readily apparent to those skilled in the art that various modifications and adaptations may be made without departing from the spirit of the invention or from the scope of the appended claims. For example, those skilled in the art will appreciate that the specific configuration of the components discussed herein may be varied considerably while maintaining component equivalence. Such equivalent but different ways and the modifications and adaptations which may be implemented to achieve them are to be included within the scope of the present invention.

What is claimed is:

1: A concentrated photovoltaic system comprising:
a first linear sub-array of a plurality of first photovoltaic cells in which each of said plurality of first photovoltaic cells faces in a first direction;
a second linear sub-array of a plurality of second photovoltaic cells in which each of said plurality of second photovoltaic cells faces in a second direction which is nonparallel to said first direction; and
an optical system configured to direct solar flux to said first and second linear sub-arrays.

2: A concentrated photovoltaic system as claimed in claim 1 wherein said optical system comprises:
a reflecting dish;
a first linear concentrator configured to receive solar flux after reflection from said dish and to direct solar flux to said first linear sub-array; and
a second linear concentrator configured to receive solar flux after reflection from said dish and to direct solar flux to said second linear sub-array.

3: A concentrated photovoltaic system as claimed in claim 2 wherein each of said first and second linear concentrators is configured as a lens.

4: A concentrated photovoltaic system as claimed in claim 3 wherein each of said lenses comprises:
an entry surface configured to direct solar flux into multiple discrete sections of said lens;
a continuous refractive index region adjacent to said entry surface;
a totally internally reflecting side profile region for each of said multiple discrete sections, said totally internally reflecting side profile regions being spaced apart from each other; and
a separate exit surface for each of said multiple discrete sections, said exit surfaces being spaced apart from each other.

5: A concentrated photovoltaic system as claimed in claim 4 wherein, for each of said lenses, each exit surface of said lens is planar and is coplanar with said exit surfaces for other ones of said multiple discrete sections of said lens.

6: A concentrated photovoltaic system as claimed in claim 2 wherein each of said first and second linear concentrators is a totally internally reflecting concentrator.

7: A concentrated photovoltaic system as claimed in claim 2 wherein:
a substantially constant refractive index solar flux transmission medium extends through said first linear concentrator to said first photovoltaic cells; and
a substantially constant refractive index solar flux transmission medium extends through said second linear concentrator to said second photovoltaic cells.

8: A concentrated photovoltaic system as claimed in claim 2 additionally comprising a frame which defines a convex shape and is positioned so that said convex shape faces said reflecting dish, wherein said first and second linear sub-arrays and said first and second linear concentrators are mounted to said frame.

9: A concentrated photovoltaic system as claimed in claim 1 wherein:
said plurality of first photovoltaic cells are electrically coupled together so that no two of said first photovoltaic cells are coupled in series;
said plurality of second photovoltaic cells are electrically coupled together so that no two of said second photovoltaic cells are coupled in series;
said concentrated photovoltaic system additionally comprises a first DC/DC converter which increases its output voltage having an input coupled to said plurality of first photovoltaic cells and configured to present a load to said plurality of first photovoltaic cells which causes said plurality of first photovoltaic cells to operate approximately at their maximum power points; and
said concentrated photovoltaic system additionally comprises a second DC/DC converter which increases its output voltage having an input coupled to said plurality of second photovoltaic cells and configured to present a load to said plurality of second photovoltaic cells which causes said plurality of second photovoltaic cells to operate approximately at their maximum power points.

10: A concentrated photovoltaic system as claimed in claim 1 wherein:
said optical system is configured to direct differing amounts of solar flux to different ones of said plurality of first photovoltaic cells; and
said optical system is configured to direct differing amounts of solar flux to different ones of said plurality of second photovoltaic cells.

11: A concentrated photovoltaic system as claimed in claim 1 wherein:
said first photovoltaic cells are positioned adjacent to one another without significant gaps there between; and
said second photovoltaic cells are positioned adjacent to one another without significant gaps there between.

12: A concentrated photovoltaic system comprising:
a reflecting dish primary concentrator;
a linear secondary concentrator configured to collect and concentrate solar flux from said primary collector; and
a sub-array of at least three collinear and coplanar photovoltaic cells configured to collect solar flux from said secondary concentrator.

13: A concentrated photovoltaic system as claimed in claim 12 additionally comprising a frame which outlines a convex shape and is positioned before a focusing region of said primary concentrator so that said convex shape faces said primary concentrator, wherein said sub-array of at least three collinear and coplanar photovoltaic cells and said linear secondary concentrator are mounted to said frame.

14: A concentrated photovoltaic system as claimed in claim 12 wherein:
said sub-array of at least three collinear and coplanar photovoltaic cells are electrically coupled together so that no two of said photovoltaic cells are coupled in series; and
said concentrated photovoltaic system additionally comprises a DC/DC boost converter having an input coupled to said photovoltaic cells and configured to present a load to said photovoltaic cells which causes said photovoltaic cells to operate approximately at their maximum power points.

15: A concentrated photovoltaic system as claimed in claim 12 wherein:
said primary and secondary concentrators are configured so that differing amounts of solar flux irradiate different ones of said sub-array of at least three collinear and coplanar photovoltaic cells.

16: A concentrated photovoltaic system as claimed in claim 12 wherein:
a solar flux transmission medium extending from said primary concentrator to said secondary concentrator is formed exclusively from air;
said secondary concentrator is configured as a lens; and
a substantially constant refractive index solar flux transmission medium extends through said lens to each of said photovoltaic cells.

17: A concentrated photovoltaic system as claimed in claim 12 wherein:
said linear secondary concentrator is a first linear secondary concentrator;
said sub-array of at least three collinear and coplanar photovoltaic cells is a first sub-array of at least three collinear and coplanar photovoltaic cells, and each of said photovoltaic cells in said first sub-array face in a first direction;
said concentrated photovoltaic system additionally comprises a second sub-array of at least three collinear and coplanar photovoltaic cells, each facing in a second direction nonparallel to said first direction; and
said concentrated photovoltaic system additionally comprises a second linear secondary concentrator configured to collect and concentrate solar flux from said primary collector and direct solar flux to said second sub-array of at least three collinear and coplanar photovoltaic cells.

18: A concentrated photovoltaic system as claimed in claim 12 wherein:
said sub-array of at least three collinear and coplanar photovoltaic cells is a first sub-array;
said photovoltaic cells in said first sub-array are positioned adjacent one another without significant gaps there between; and
said concentrated photovoltaic system additionally comprises a second sub-array of at least three collinear and coplanar photovoltaic cells positioned adjacent one another without significant gaps there between, said second sub-array being spaced apart from and parallel to said first sub-array, and said second sub-array being configured to collect solar flux from said secondary concentrator.

19: A concentrated photovoltaic system as claimed in claim 18 wherein said linear secondary concentrator is configured as a lens comprising:
an entry surface configured to direct solar flux into at least two discrete sections of said lens;
a continuous refractive index region adjacent to said entry surface;
a totally internally reflecting side profile region for each of said at least two discrete sections, said totally internally reflecting side profile regions being spaced apart from each other; and
a separate exit surface for each of said at least two discrete sections, said exit surfaces being spaced apart from each other.

20: A concentrated photovoltaic system as claimed in claim 19 wherein each exit surface is planar and is coplanar with said exit surfaces for other ones of said at least two discrete sections.
